(19) United States
(12) Patent Application Publication
(10) Pub. No.: US 2025/0030328 A1
(43) Pub. Date: Jan. 23, 2025

(54) ADAPTIVE BURST MODE CONTROL

(71) Applicant: Texas Instruments Incorporated, Dallas, TX (US)

(72) Inventors: Aki Li, MAOMING CITY (CN); Desheng Guo, SHANGHAI (CN); Chen Jiang, SUGAR LAND, TX (US); Qing Ye, KATY, TX (US)

(21) Appl. No.: 18/356,221

(22) Filed: Jul. 21, 2023

(51) Int. Cl. H02M 1/00; H02M 1/088; H02M 3/335

(52) U.S. Cl. CPC H02M 1/0035; H02M 1/0009; H02M 1/0012; H02M 1/088; H02M 3/33576; H03K 19/20

(57) ABSTRACT

In described examples, a device includes a pulse width modulation (PWM) control circuit and a burst mode logic circuit. An input of the burst mode logic circuit is coupled to an output of the PWM control circuit. The burst mode logic circuit is configured to receive a feedback signal from a secondary side of a power conversion circuit. The burst mode logic circuit is configured to suppress a sleep period of a burst mode in response to a magnitude of the feedback signal exceeding a nominal load threshold voltage. The PWM control circuit continues to operate in the burst mode while the burst mode logic circuit suppresses the sleep period.

### TECHNICAL FIELD

This application relates generally to pulse width modulation (PWM) control of power converters, and more particularly to burst mode PWM control of power converters under no-load or light-load conditions.

### BACKGROUND

In some examples, a PWM signal is used to control a switched device such as a power converter. In some examples, under normal loading, a power converter operates at relatively high efficiency. However, under no-load or light-load conditions, provision of continuous inductor current can result in reduced converter efficiency. Accordingly, under no-load or light-load conditions, a burst mode is used in which PWM signals are passed to the switched device during relatively brief burst periods, and not during intervals between the burst periods.

### SUMMARY

In described examples, a device includes a pulse width modulation (PWM) control circuit and a burst mode logic circuit. An input of the burst mode logic circuit is coupled to an output of the PWM control circuit. The burst mode logic circuit is configured to receive a feedback signal from a secondary side of a power conversion circuit. The burst mode logic circuit is configured to suppress a sleep period of a burst mode in response to a magnitude of the feedback signal exceeding a nominal load threshold voltage. The PWM control circuit continues to operate in the burst mode after the burst mode logic circuit begins to suppress the sleep period.

### BRIEF DESCRIPTION OF THE DRAWINGS

FIG. 1 is a functional block and circuit diagram of an example power converter system.

FIG. 2 is a set of graphs of example burst mode signals of the power converter system of FIG. 1.

FIG. 3 is a logic gate and functional block diagram of the burst mode logic circuit of FIG. 1.

FIG. 4 is a timing diagram showing an example of application of a burst mask to a PWM control signal to produce a burst mode PWM signal.

FIG. 5A is a timing diagram illustrating an example process for generating the burst mask of FIG. 4.

FIG. 5B is the example process for generating the burst mask of FIG. 4, as illustrated in FIG. 5A.

FIG. 6 is a timing diagram of an example process for transitioning from a no-load or low-load condition of the power converter system of FIG. 1 to a normally loaded condition of the power converter system of FIG. 1, using a burst mode logic circuit that does not include the comparator of FIG. 3.

FIG. 7 is a timing diagram of an example process for transitioning from a no-load or low-load condition of the power converter system of FIG. 1 to a normally loaded condition of the power converter system of FIG. 1, using the burst mode logic circuit of FIG. 3.

FIG. 8 is a process for transitioning the power converter system from burst mode to normal mode in response to a nominal load condition.

### DETAILED DESCRIPTION

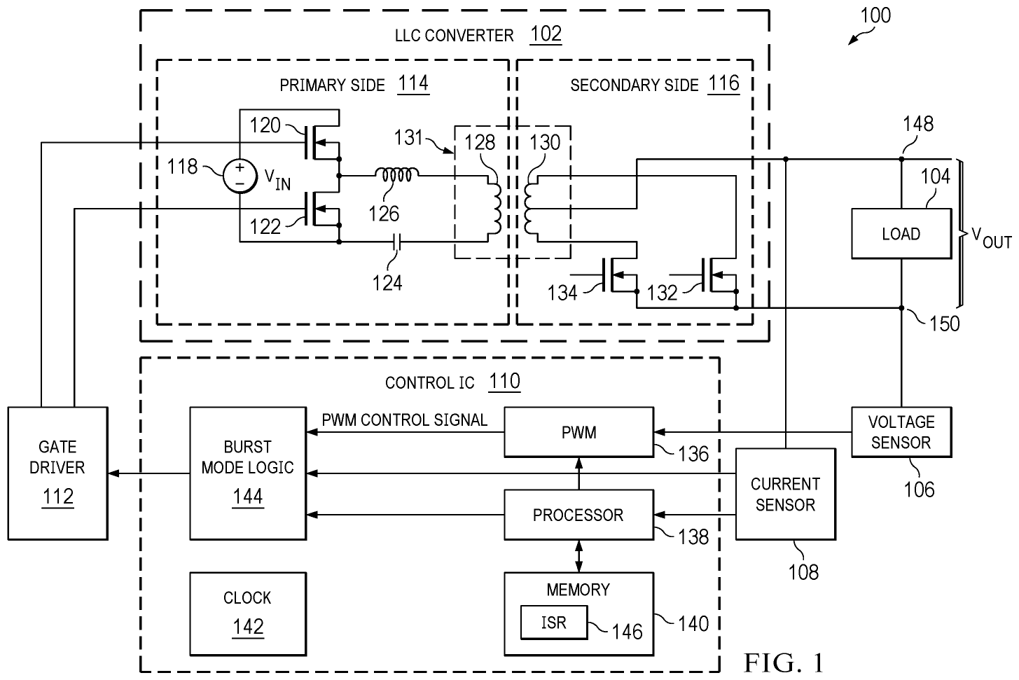

FIG. 1 is a functional block and circuit diagram of an example power converter system 100. The power converter system 100 includes an LLC (inductor-inductor-capacitor) converter 102, a load 104, a voltage sensor 106, a current sensor 108, a control integrated circuit (IC) 110, and a gate driver circuit 112.

The LLC converter 102 includes a primary side 114 and a secondary side 116. The primary side 114 includes a voltage source 118, a high side transistor 120, a low side transistor 122, a capacitor 124, an inductor 126, and a primary winding 128. Together, the inductor 126, a magnetizing inductance of the primary winding 128, and the capacitor 124 form a resonant tank circuit. Accordingly, the LLC converter 102 is referred to as a resonant power converter. The secondary side 116 includes a secondary winding 130, a first rectifier transistor 132, and a second rectifier transistor 134. Together, the primary winding 128 and the secondary winding 130 form a transformer 131. The inductor 126 may be, for example, an external inductor or a leakage inductance of the transformer 131.

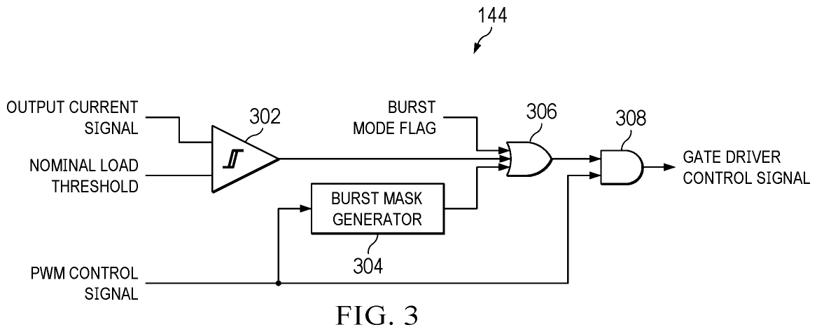

The control IC 110 includes a pulse width modulation (PWM) circuit 136, a processor 138, a memory 140, a clock circuit 142, and a burst mode logic circuit 144. The burst mode logic circuit 144 is further described with respect to FIG. 3. The memory 140 includes a memory circuit storing instructions for performing an interrupt service routine (ISR) 146 for switching between a burst mode for operating the LLC converter 102 and a normal mode for operating the LLC converter 102. In some examples, the ISR 146 is stored in a flash memory bank of the memory 140.

On the primary side 114, a positive terminal of the voltage source 118 is connected to a first terminal of the high side transistor 120. A second terminal of the high side transistor 120 is connected to a first terminal of the low side transistor 122 and a first terminal of the inductor 126. A second terminal of the inductor 126 is connected to a first terminal of the primary winding 128. The primary winding 128 is magnetically coupled to the secondary winding 130. A second terminal of the primary winding 128 is connected to a first terminal of the capacitor 124. A second terminal of the capacitor 124 is connected to a second terminal of the low side transistor 122 and a negative terminal of the voltage source 118.

On the secondary side 116, a first terminal of the secondary winding 130 is connected to a first terminal of the first transistor 132. A second terminal of the secondary winding 130 is connected to a first terminal of the second transistor 134. A center tap of the secondary winding 130 is connected to an input of the current sensor 108 and a first terminal of the load 104 via a first output terminal 148. A second terminal of the load 104 is connected, via a second output terminal 150, to second terminals of the first and second transistors 132 and 134. An output voltage V_{OUT} of the LLC converter 102 is a voltage between the first and second output terminals 148 and 150, that is, a voltage across the load 104. The second output terminal 150 is connected to an input of the voltage sensor 106. The first and second transistors 132 and 134 are controlled using respective control terminals so that the first and second transistors 132 and 134 form a rectifier to rectify current on the secondary side 116.

Control terminals of the first and second transistors 132 and 134 are, for example, gates of respective metal-oxide-semiconductor field-effect transistors (MOSFETS). In some examples, the first and second transistors 132 are n-channel MOSFETS. A source of the first transistor 132 is connected to the positive terminal of the voltage source 118. A drain of the first transistor 132 is connected to a drain of the second transistor 134 and the first terminal of the inductor 126. A drain of the second transistor 134 is connected to the second terminal of the capacitor 124 and the negative terminal of the voltage source 118. The first and second transistors 132 and 134 serve a switching function for the LLC converter 102, controlling current flow through the primary coil 128 and, accordingly, transfer of energy from the primary coil 128 to the secondary coil 130.

An output of the voltage sensor 106 is connected to an input of the PWM circuit 136 (e.g., by a first optocoupler). An output of the PWM circuit 136 is connected to a first input of the burst mode logic circuit 144. A first output of the current sensor 108 is connected to a second input of the burst mode logic circuit 144 and a first input of the processor 138 (e.g., by a second optocoupler). The processor 138 is connected to communicate with the memory 140, and a second output of the processor 138 is connected to a third input of the burst mode logic circuit 144. An output of the burst mode logic circuit 144 is connected to an input of the gate driver 112. A first output of the gate driver 112 is connected to the control terminal of the high side transistor 120. A second output of the gate driver 112 is connected to the control terminal of the low side transistor 122.

When the high side transistor 120 is on and the low side transistor 122 is off, current flowing from the positive terminal of the voltage source 118, through the inductor 126, and through the primary winding 128 increases. While current flows through the primary winding 128 towards the capacitor 124, the capacitor 124 charges and the primary winding 128 generates a magnetic flux that causes a magnetic core (not shown) to store magnetic energy with a first polarity. When the high side transistor 120 is off and the low side transistor 122 is on, current flowing from the capacitor 124, through the primary winding 128, through the inductor 126, towards the negative terminal of the voltage source 118 increases. While current flows through the primary winding 128 towards the negative terminal of the voltage source 118, the capacitor 124 discharges and the primary winding 128 generates a magnetic flux that causes the magnetic core to store magnetic energy with a second polarity. Magnetic flux generated by the primary winding 128 induces current in the secondary winding 130 that is rectified by the first and second transistors 132 and 134 to provide direct current (DC) power to the load 104.

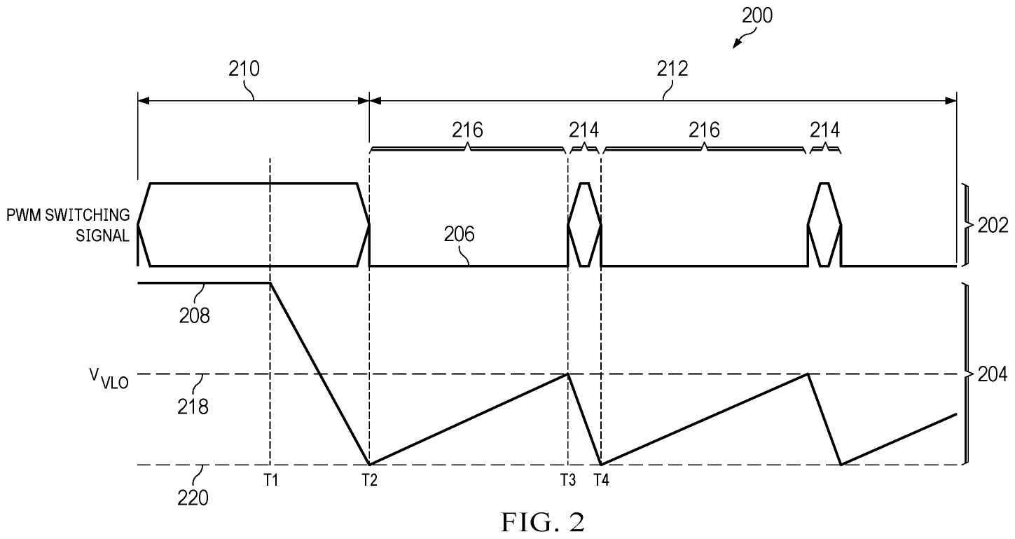

In some resonant power converters, as output current demand (current demand of the load 104) falls, a switching frequency of transistors controlling power transfer is increased to reduce power output. In the LLC converter 102, this corresponds to increasing a switching frequency of the high side and low side transistors 120 and 122. However, in low-load conditions, a high switching frequency and a reduced power output may result in reduced efficiency due to increased switching losses. In some examples, a burst mode is used to maintain a target output voltage level within a hysteresis range, and to maintain a relatively high efficiency, while the LLC converter 102 operates in low-load conditions. The burst mode is further described with respect to FIGS. 2 through 5B.

FIG. 2 is a set of graphs 200 of example burst mode signals of the power converter system 100 of FIG. 1. The same reference numbers or other reference designators are used in the drawings to designate the same or similar (structurally and/or functionally) features. The graphs 200 include a first graph 202 and a second graph 204. The first graph 202 shows an output signal of the PWM circuit 136, referred to here as a PWM switching signal 206. The second graph 204 shows a voltage (V_{VLO}) of a voltage loop output 208. V_{VLO} is a control loop voltage used by the ISR 146 to regulate V_{OUT}. V_{VLO} is given by Equation 1:

$${V}_{VLO} = ( {V}_{REF} - {V}_{OUT} ) \times compensator \qquad Equation 1$$

In Equation 1, V_{REF} is a reference voltage (not shown), V_{OUT} is sensed by the voltage sensor 106, and compensator is a value provided by a control loop regulation function (which may be implemented in software or hardware), such as a proportional-integral-derivative (PID) controller (not shown). V_{VLO} is used by the PWM circuit 136 to determine a switching frequency to regulate the output voltage to the reference voltage, and the compensator value is used by the control IC 110 to adjust V_{VLO} to facilitate this function.

The PWM switching signal 206 includes a period corresponding to normal operation 210 and a period corresponding to burst mode operation 212. The burst mode 212 has a burst period 214 during which the high side and low side transistors 120 and 122 are alternatingly turned on and off by gate driver 112 to generate a burst of pulses to start oscillation of the resonant converter at a level sufficient to recharge an output capacitor. Burst interval periods 216 are located between the burst periods 214. During the burst interval periods 216, the high side and low side transistors 120 and 122 are turned off. Accordingly, given the off state, the burst interval periods 216 also may be referred to as sleep periods 216.

During periods when the PWM switching signal 206 is switching between voltages corresponding to logical one and logical zero—that is, throughout normal operation 210, and during burst periods 214 of burst mode operation 212—the gate driver circuit 112 alternatingly drives the high side and low side transistors 120 and 122 on and off. These periods of actively switched operation are represented as eye patterns. Sleep periods 216 are represented as a constant value (a straight line).

During normal operation 210, V_{VLO} 208 is maintained at an approximately constant level. At T1, the load is removed (suddenly or gradually), which causes V_{VLO} 208 to fall. At time T2, the ISR 146, as executed by the processor 138, detects a no-load or low-load condition (also referred to herein as an underloaded condition) and signals the PWM circuit 136 and the burst mode logic circuit 144 to initiate burst mode 212. An underloaded condition can correspond to, for example, an average current demand of the load 104 being less than an average current that high side and low side transistors 120 and 122 can efficiently cause the primary coil 128 to induce in the secondary coil during normal operation 210.

During burst mode 212, the PWM switching signal 206 provides higher frequency pulses (higher frequency as compared to normal mode 210) to control the high side and low side transistors 120 and 122 to switch more frequently. A higher switching rate results in a higher rate of power transfer from the primary coil 128 to the secondary coil 130. This enables the LLC converter 102 to regulate V_{VLO} 208—and accordingly, output voltage—while significantly reducing total power transferred across the transformer 131 by providing power transfer periods with relatively high frequency but relatively low duration. Note that during sleep periods 216 V_{OUT} decreases as an output capacitance (not shown) discharges, which causes V_{VLO} 208 to increase (see Equation 1).

At T3, V_{VLO} 208 reaches (or rises above) a high threshold 218, reflecting a corresponding reduction in V_{OUT} as detected by the voltage sensor 106. In response, the PWM circuit 136 and the burst mode logic circuit 144 begin a burst period 214 to transfer energy from the primary coil 128 to the secondary coil 130 to increase V_{OUT} and (correspondingly) decrease V_{VLO} 208. At T4, V_{VLO} 208 reaches (or falls below) a low threshold 220, reflecting a corresponding increase in V_{OUT} as detected by the voltage sensor 106. In response, the PWM circuit 136 and the burst mode logic circuit 144 end the burst period 214, so that a sleep period 216 begins. The ISR 146, as executed by the processor 138, ends the burst mode 212 when V_{VLO} 208 indicates a normal load condition. In some examples, a voltage swing between the high threshold 218 and the low threshold 220 during burst mode 212 is larger than a corresponding voltage swing (not shown in FIG. 2) during normal operation 210.

FIG. 3 is a logic gate and functional block diagram of the burst mode logic circuit 144 of FIG. 1. The burst mode logic circuit 144 includes a comparator 302, a burst mask generator 304, an OR logic gate 306, and an AND logic gate 308. A first input of the comparator 302 is connected to the output of the current sensor 108 (e.g., via an optocoupler) to receive an output current signal that indicates an output current of the LLC converter 102. The output current signal can correspond to, for example, an instantaneous voltage across a resistor connected in series with the load 104. The voltage across the resistor is captured by a capacitor using a monostable multivibrator. In response to a trigger signal, the monostable multivibrator provides a short duration pulse to rapidly close and then open a switch (the resistor, capacitor, multivibrator, and switch are not shown). A second input of the comparator 302 receives a nominal load threshold voltage, which is used to indicate a return from an underloaded condition to a normal load condition.

An output of the comparator 302 is connected to a first input of the OR logic gate 306. A second input of the OR logic gate 306 receives a burst mode flag that indicates whether the power converter system 100 is currently operating in normal mode 210 or burst mode 212. A burst mode flag with a voltage corresponding to a logical one indicates operation in normal mode 210, and a burst mode flag with a voltage corresponding to a logical zero indicates operation in burst mode 212. An input of the burst mask generator 304 receives a PWM control signal from the PWM circuit 136. An output of the burst mask generator 304 is connected to a third input of the OR logic gate 306.

An output of the OR logic gate 306 is connected to a first input of the AND logic gate 308. A second input of the AND logic gate 308 receives the PWM control signal. An output of the AND logic gate 308 is connected to the gate driver circuit 112, and provides a gate driver control signal.

As described above, the nominal load threshold voltage is used to indicate whether the power converter system 100 is in a normal load condition, or an underloaded condition. A normal load condition is indicated if the output current signal is greater than the nominal load threshold voltage. Accordingly, in response to a voltage of the output current signal being less than the nominal load threshold voltage, indicating an underloaded condition, the comparator 302 outputs a voltage corresponding to a logical zero (e.g., a relatively low voltage). In response to a voltage of the output current signal exceeding the nominal load threshold voltage, indicating a normal load condition, the comparator 302 transitions to outputting a voltage corresponding to a logical one (e.g., a relatively high voltage). In some examples, the comparator 302 also includes hysteresis in its threshold voltage, avoiding the comparator 302 transitioning from outputting a logical one to outputting a logical zero due to random or transient events such as line noise. In some examples, a different type of comparator is used to determine a transition from an underloaded condition to a normal load condition, in response to the output current signal and the nominal load threshold voltage.

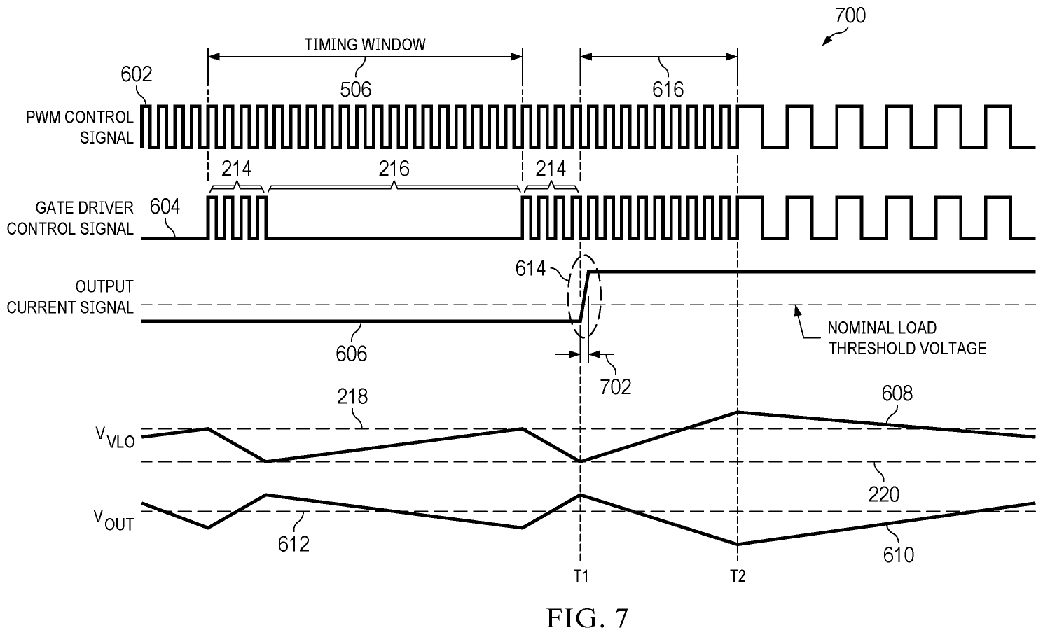

The comparator 302 is used to suppress a sleep period 216, in response to detecting a nominal load condition, while the power converter system 100 continues to operate in burst mode. Suppression of the sleep period 216 corresponds to the output of the comparator 302 being a logical one, and may occur (in whole or in part) during a burst period 214. Contemporaneously with the comparator 302 suppressing the sleep period 216, the ISR 146 (as executed by the processor 138) processes signal information indicating the nominal load condition, and on completion of the processing, returns the power converter system 100 to normal mode 210. Suppression of the sleep period 216 by the comparator 302 is further discussed with respect to FIG. 7.

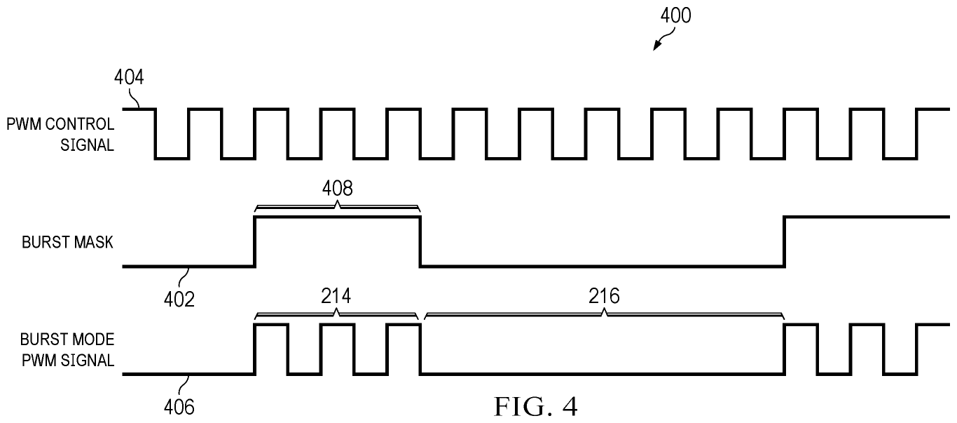

FIG. 4 is a timing diagram 400 showing an example of application of a burst mask 402 to a PWM control signal 404 to produce a burst mode PWM signal 406. The burst mask 402 is, for example, a square wave, with logical one portions of duration corresponding to respective burst periods 214 alternating with logical zero portions of duration corresponding to respective sleep periods 216. The burst mode PWM signal 406 corresponds to the PWM switching signal 206 during burst mode 212. The burst mode PWM signal 406 is the output of the AND logic gate 308, which receives the PWM control signal 404 and the burst mask 402 as inputs. That is, during burst mode 212, the burst mode PWM signal 406 output by the AND logic gate 308 corresponds to the PWM control signal 404 during burst periods 214, and otherwise has the logical zero value. The duration of a pulse 408 of the burst mask 402—and correspondingly, an extent to which the output capacitance is recharged to increase V_{OUT} during a burst period 214—is determined in response to V_{VLO} 208.

Returning to FIG. 3, if either the burst mode flag has the logical value one (normal operation) or the output of the comparator 302 has the logical one value (detection of a nominal load condition), then the OR logic gate 306 outputs the logical one value, regardless of the output of the burst mask generator 304. If both the burst mode flag and the output of the comparator 302 have the logical zero value, then the OR logic gate 306 outputs the burst mask 402 generated by the burst mask generator 304. Accordingly, if either the burst mode flag or the output of the comparator 302 have the logical one value, then the AND logic gate 308 outputs the PWM control signal 404. If both the burst mode flag and the output of the comparator 302 have the logical zero value, then the AND logic gate 308 outputs the burst mode PWM signal 406. In other words, the AND logic gate 308 outputs the burst mode PWM signal 406 only if two conditions are met, namely, both the bust mode flag indicates burst mode and the comparator 302 does not detect a normal load condition.

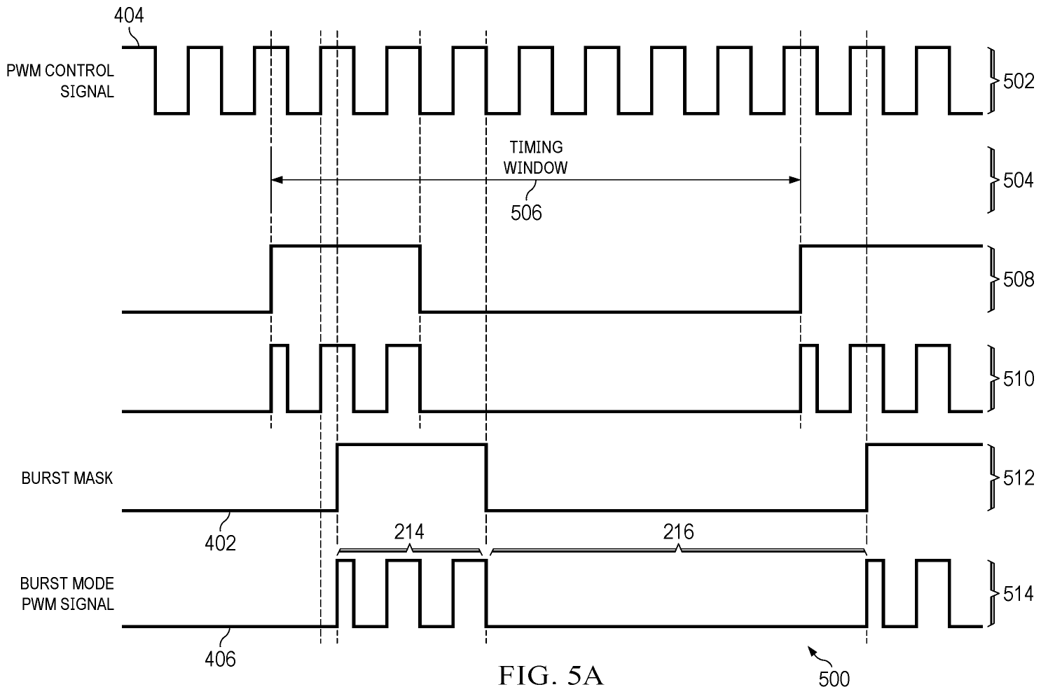

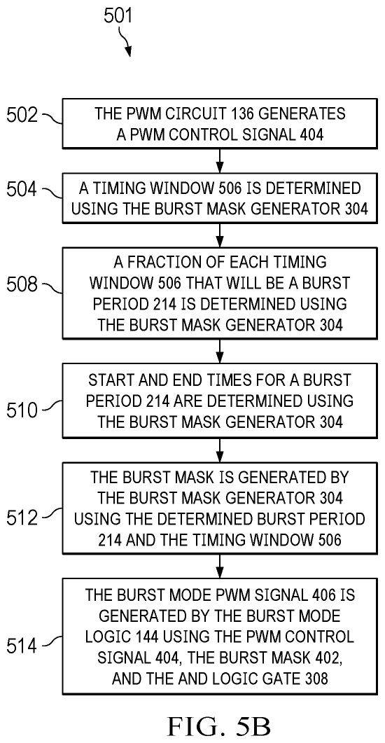

FIG. 5A is a timing diagram 500 illustrating an example process 501 for generating the burst mask 402 of FIG. 4, and FIG. 5B is the example process 501. Portions of the FIG. 5A timing diagram 500 corresponding to respective FIG. 5B steps of the process 501 are labeled with the corresponding step identification numbers.

In step 502, the PWM circuit 136 generates a PWM control signal 404. In some examples, steps 504 and 508 through 512 are performed using the burst mask generator 304, and step 514 is performed using the burst mode logic circuit 144. In step 504, a timing window 506 is determined. The timing window 506 has the duration of one burst mode cycle, that is, a burst period 214 and a following (next/subsequent) sleep period 216. In some examples, a timing window 506 is selected so that the frequency of burst periods 214 is at least 20 kilohertz (kHz) (or other above-audible frequency), so that burst mode switching will not produce an audible noise. A frequency of 20 kHz corresponds to a burst mode cycle duration of 50 microseconds.

In step 508, a fraction of each burst mode cycle that will be a burst period 214 is determined. In some examples, this fraction is selected to reduce output voltage ripple.

In step 510, start and end times for a burst period 214 are determined. In some examples, burst period 214 duration is determined as a number of PWM control signal 404 duty cycles. In some examples, a start time of a timing window 506 is used as the start time for the burst period 214. In some examples, the start time of a timing window 506 falls at a random time with respect to a duty cycle of the PWM control signal 404. The start time of a burst period 214 can be adjusted so that a first PWM pulse of the burst period 214 has a duty cycle selected to reduce output voltage ripple. In some examples, a 25% duty cycle is selected for a first PWM pulse of a burst period 214 of a PWM control signal 404 with a 50% duty cycle. (In some examples, other PWM control signal 404 duty cycles and/or first PWM pulse duty cycles are used.) The start of the burst period 214 can be determined to ensure that a first PWM pulse has a 25% duty cycle using an internal count of the PWM circuit 136 that is used to determine rising and falling edges of PWM pulses. In the illustrated example, a burst period 214 starts at a count corresponding to the rising edge of a PWM pulse plus a count corresponding to half of the duty cycle of the PWM control signal 404, and ends at a count corresponding to a falling edge of a PWM pulse.

In step 512, the burst mask is generated by the burst mask generator 304 using the determined burst period 214 and the timing window 506. In step 514, the burst mode PWM signal 406 is generated by the burst mode logic circuit 144 using the PWM control signal 404, the burst mask 402, and the AND logic gate 308.

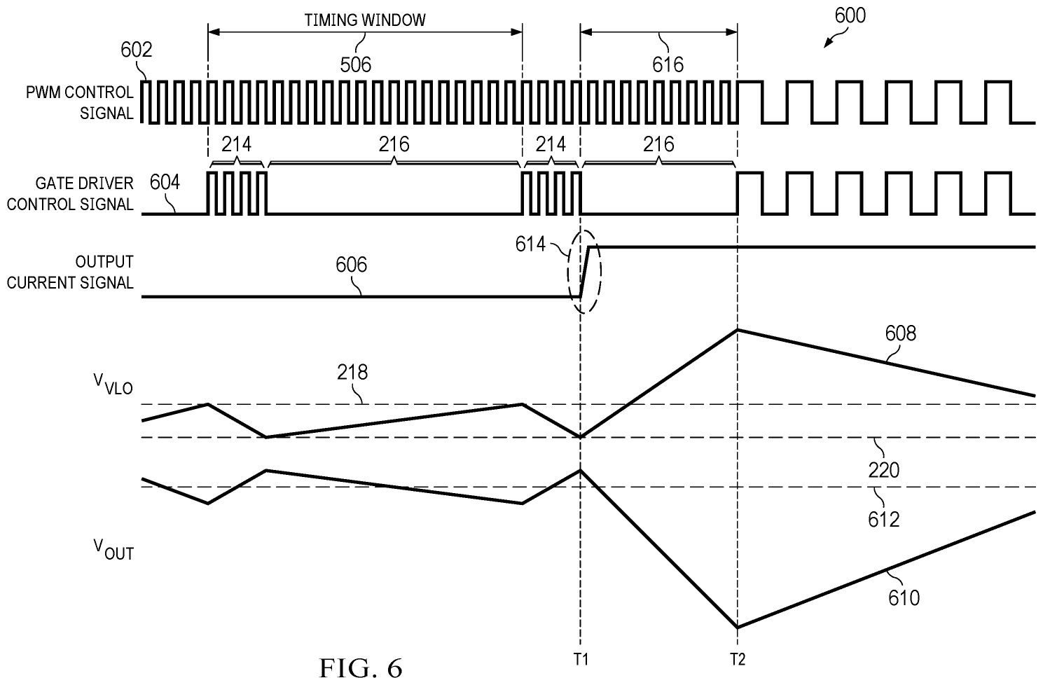

FIG. 6 is a timing diagram 600 of an example process for transitioning from an underloaded condition of the power converter system 100 of FIG. 1 to a normally loaded condition of the power converter system of FIG. 1, using a burst mode logic circuit 144 that does not include the comparator 302 of FIG. 3. A PWM control signal 602 is applied to the burst mode logic circuit 144 to generate a gate driver control signal 604. An output current signal 606 shows a voltage indicating a current measured by the current sensor 108. A voltage loop output signal (V_{VLO}) 608 and an output voltage signal (V_{OUT}) 610 are also shown.

As described with respect to FIG. 2, during burst mode 212, the PWM circuit 136, burst mode logic circuit 144, and gate driver circuit 112 together control the high side and low side transistors 120 and 122 so that V_{VLO} 608 is maintained between the high threshold 218 and the low threshold 220. This causes V_{OUT} 610 to be maintained near a corresponding average V_{OUT} 612.

At T1, the output current signal 606 has a rising edge 614, transitioning from a value indicating an underloaded condition to a value indicating a normal load condition. A control loop interval 616 of the ISR 146 refers to a time taken for the processor 138, executing the instructions of the ISR 146 in response to the output current signal 606 transition, to change the burst mode flag (see FIG. 3) from zero to one and switch the PWM circuit 136 from burst mode operation to normal mode operation. In some examples, the delay represented by the control loop interval 616 also includes time taken for a control loop regulation function to begin providing compensator values (see Equation 1).

In some examples, the control loop interval 616 of the ISR 146 has a duration (for example, 20 microseconds) that can substantially overlap the burst period interval 216. This causes V_{VLO} 608 to be uncontrolled during a period of high current demand of the load 104. In response, V_{VLO} 608 increases outside the hysteresis interval defined by the high and low thresholds 218 and 220, resulting in a relatively large undershoot of V_{OUT} 610. In other words, V_{OUT} 610 has a relatively large negative deviation from the intended average V_{OUT} 612. Normal mode control of V_{OUT} 610 resumes at T2, after the end of the control loop interval 616 of the ISR 146, after which V_{VLO} 608 and V_{OUT} 610 return toward respective intended ranges.

FIG. 7 is a timing diagram of an example process for transitioning from an underloaded condition of the power converter system 100 of FIG. 1 to a normally loaded condition of the power converter system of FIG. 1, using the burst mode logic 144 of FIG. 3. As the output current signal 606 increases along its rising edge 614, the output current signal 606 exceeds the nominal load threshold. This causes the output of the comparator 302 to transition to a logical one. As a result, the output of the OR logic gate 306 becomes a constant logical one, so that the output of the gate driver control signal 308 equals the PWM control signal 602. In other words, in response to the comparator 302 detecting a transition to a normal load condition, the sleep period 216 is suppressed.

Suppressing the sleep period 216 at T1 means that, in response to the rising edge 614, the FIG. 7 gate driver control signal 604 continues to provide continuous burst period 214 control to the high side and low side transistors 120 and 122. This is in contrast to the FIG. 6 approach, in which there is a delay following T1 during which the sleep period 216 persists. This enables the primary side 114 to transfer energy to the secondary side 116 while the control loop interval 616 of the ISR 146 is ongoing, regardless of normal timing of sleep periods 216. In some examples, a hardware delay 702 (of the burst mode logic circuit 144) to suppress the sleep period 216 is much shorter than a software delay to complete the control loop interval 616 of the ISR 146. In an example, this hardware delay 702 is 60 nanoseconds. Accordingly, V_{OUT} 610 undershoot is reduced and V_{OUT} 610 stays closer to the intended average V_{OUT} 612 until T2, when the power converter system 100 transitions to normal mode operation.

After T1, the PWM control circuit 136 continues to operate in burst mode 212 because the PWM control circuit 136 has not yet been signaled to by the processor 138 to transition to normal mode 210. After T2, following completion of the ISR control loop 146 detecting the normal load condition, the power converter system 100 returns to normal mode 210 regulation of V_{OUT} 610.

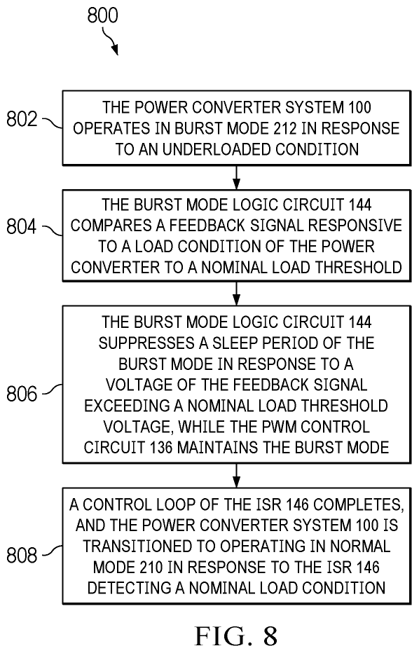

FIG. 8 is a process 800 for transitioning the power converter system 100 from burst mode 210 to normal mode 212 in response to a nominal load condition. In step 802, the power converter system 100 operates in burst mode 212 in response to an underloaded condition. In step 804, the burst mode logic circuit 144 compares a feedback signal responsive to a load condition of the power converter to a nominal load threshold. In an example, the feedback signal can be a voltage of the output current signal 606, which indicates an output current of the LLC converter 102 as measured by the current sensor 106. In step 806, the burst mode logic circuit 144 suppresses a sleep period of the burst mode in response to a voltage of the feedback signal exceeding a nominal load threshold voltage, while the PWM control circuit 136 continues to operate in the burst mode 212 (that is, the control loop of the ISR 146 has not yet completed, so the PWM control circuit 136 remains in burst mode 212). The voltage of the feedback signal exceeding the nominal load threshold voltage indicates a nominal load condition. In step 808, a control loop of the ISR 146 completes, and the processor 138 signals the power converter system 100 to transition to operating in normal mode 210 in response to the ISR 146 detecting a nominal load condition.

Modifications are possible in the described examples, and other examples are possible, within the scope of the claims.

In some examples, the burst control circuits and processes described herein can be used to control PWM-controlled devices other than half-bridge LLC converters, such as buck, boost, or buck-boost converters, half-bridge or full-bridge devices, DC or AC input devices, DC or AC output devices, or other devices that provide or regulate power, including across an inductor or transformer or otherwise.

In some examples, a normal load condition is applied during a burst period 214, or after the beginning of a sleep period 216.

In some examples, the statement that “the burst mode logic circuit is configured to suppress a sleep period of a burst mode in response to a magnitude of the feedback signal exceeding a nominal load threshold voltage, while the PWM control circuit continues to operate in the burst mode” refers to behavior of the burst mode logic circuit 144 as described with respect to FIGS. 3 and 7.

The term “couple” is used throughout the specification. The term may cover connections, communications, or signal paths that enable a functional relationship consistent with this description. For example, if device A provides a signal to control device B to perform an action, in a first example device A is coupled to device B, or in a second example device A is coupled to device B through intervening component C if intervening component C does not substantially alter the functional relationship between device A and device B such that device B is controlled by device A via the control signal provided by device A.

In this description, the term “and/or” (when used in a form such as A, B and/or C) refers to any combination or subset of A, B, C, such as: (a) A alone; (b) B alone; (c) C alone; (d) A with B; (e) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin”, “ball” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

This disclosure has attributed functionality to control IC 110, PWM circuit 136, processor 138, and burst mode logic circuit 144. Control IC 110, PWM circuit 136, processor 138, and/or burst mode logic circuit 144 may include one or more processors. Control IC 110, PWM circuit 136, processor 138, and/or burst mode logic circuit 144 may include any combination of integrated circuitry, discrete logic circuitry, analog circuitry, such as one or more microprocessors, microcontrollers, digital signal processors, application specific integrated circuits, central processing units, graphics processing units, field-programmable gate arrays, and/or any other processing resources. In some examples, control IC 110, PWM circuit 136, processor 138, and burst mode logic circuit 144 may include multiple components, such as any combination of the processing resources listed above, as well as other discrete or integrated logic circuitry, and/or analog circuitry.

The techniques described in this disclosure may also be embodied or encoded in an article of manufacture including a non-transitory computer-readable storage medium, such as memory 140. Example non-transitory computer-readable storage media may include random access memory (RAM), read-only memory (ROM), programmable ROM, erasable programmable ROM, electronically erasable programmable ROM, flash memory, a solid-state drive, a hard disk, magnetic media, optical media, or any other computer readable storage devices or tangible computer readable media. The term “non-transitory” may indicate that the storage medium is not embodied in a carrier wave or a propagated signal. In certain examples, a non-transitory storage medium may store data that can, over time, change (e.g., in RAM or cache).

While the use of particular transistors are described herein, other transistors (or equivalent devices) may be used instead with little or no change to the remaining circuitry. For example, a metal-oxide-silicon FET (“MOSFET”) (such as an n-channel MOSFET, nMOSFET, or a p-channel MOSFET, pMOSFET), a bipolar junction transistor (BJT—e.g. NPN or PNP), insulated gate bipolar transistors (IGBTs), and/or junction field effect transistor (JFET) may be used in place of or in conjunction with the devices disclosed herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples may be included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

1. A device comprising:
a pulse width modulation (PWM) control circuit including an output; and
a burst mode logic circuit including an input and an output, the input of the burst mode logic circuit coupled to the output of the PWM control circuit, and the burst mode logic circuit configured to receive a feedback signal from a secondary side of a power conversion circuit;
wherein the burst mode logic circuit is configured to suppress a sleep period of a burst mode in response to a magnitude of the feedback signal exceeding a nominal load threshold voltage, while the PWM control circuit continues to operate in the burst mode.

2. The device of claim 1, wherein the burst mode logic circuit includes a comparator including a first input and a second input, the comparator configured to receive the feedback signal at its first input, and the comparator configured to receive the nominal load threshold voltage at its second input.

3. The device of claim 2, wherein the burst mode logic circuit includes:
a burst mask generator including an input and an output, the input of the burst mask generator coupled to the output of the PWM control circuit;
an OR logic gate having a first input, a second input, and a third input, the first input of the OR logic gate coupled to the output of the comparator, the second input of the OR logic gate coupled to the output of the burst mask generator, and the OR logic gate configured to receive a burst mode flag at its third input.

4. The device of claim 3, wherein the burst mode logic circuit includes an AND logic gate having a first input, a second input, and an output, the first input of the AND logic gate coupled to the output of the OR logic gate, and the second input of the AND logic gate coupled to the output of the PWM control circuit.

5. The device of claim 1, wherein the PWM control circuit includes an input, the input of the burst mode logic circuit is a first input of the burst mode logic circuit, the feedback signal is a first feedback signal, and the burst mode logic circuit includes a second input;
the device further comprising:
a memory circuit storing instructions that, when executed, are configured to perform an interrupt service routine for determining a load state of the power conversion circuit; and
a processor coupled to executively communicate with the memory circuit, the processor including an input, a first output, and a second output, the processor configured to receive a second feedback signal at its first input, the first output of the processor coupled to the input of the PWM control circuit, and the second output of the processor coupled to the second input of the burst mode logic circuit.

6. A system comprising:
a current sensor having an input and an output;
a pulse width modulation (PWM) control circuit having an input and an output, the input of the PWM control circuit coupled to the output of the current sensor;
a burst mode logic circuit having a first input, a second input, and an output, the first input of the burst mode logic circuit coupled to the output of the PWM control circuit, and the second input of the burst mode logic circuit coupled to the output of the current sensor;
a gate driver circuit having an input and an output, the input of the gate driver circuit coupled to the output of the burst mode logic circuit; and
a switch having a first terminal, a second terminal, and a control terminal, the control terminal of the switch coupled to the output of the gate driver circuit;
wherein the burst mode logic circuit is configured to suppress a sleep period of a burst mode in response to a voltage of the first input of the burst mode logic circuit exceeding a nominal load threshold voltage, while the PWM control circuit continues to operate in the burst mode.

7. The system of claim 6,
wherein the switch is a first switch, and wherein the output of the gate driver circuit is a first output of the gate driver circuit, the gate driver circuit having a second output;
the system further comprising a second switch having a first terminal, a second terminal, and a control terminal, the first terminal of the first switch coupled to the first terminal of the second switch, and the control terminal of the second switch coupled to the second output of the gate driver circuit.

8. The system of claim 7, the system further comprising an inductor-inductor-capacitor (LLC) power converter, the LLC power converter including the first switch and the second switch, and the current sensor configured to measure an output current of the LLC power converter.

9. The system of claim 6, wherein the switch is a first switch, the output of the gate driver circuit is a first output of the gate driver circuit, the gate driver circuit having a second output, the input of the PWM control circuit is a first input of the PWM control circuit, and the PWM control circuit has a second input, the system further comprising:
a capacitor including a first terminal and a second terminal;
an inductor;
a voltage sensor including an input and an output, the input of the voltage sensor coupled to the inductor, and the output of the voltage sensor coupled to the second input of the PWM control circuit; and
a second switch having a first terminal, a second terminal, and a control terminal, the first terminal of the first switch coupled to the first terminal of the second switch, the second terminal of the second switch coupled to the second terminal of the capacitor, and the control terminal of the second switch coupled to the second output of the gate driver circuit.

10. The system of claim 9,
wherein the inductor is a secondary coil;
the system further including a primary coil;
wherein the first and second switches are coupled to control power transfer from the primary coil to the secondary coil.

11. The system of claim 6, wherein the burst mode logic circuit includes a comparator including a first input and a second input, the first input of the comparator coupled to the second input of the burst mode logic circuit, and the comparator configured to receive the nominal load threshold voltage at its second input.

12. The system of claim 11, wherein the burst mode logic circuit includes:
a burst mask generator including an input and an output, the input of the burst mask generator coupled to the first input of the burst mode logic circuit;
an OR logic gate having a first input, a second input, and a third input, the first input of the OR logic gate coupled to the output of the comparator, the second input of the OR logic gate coupled to the output of the burst mask generator, and the OR logic gate configured to receive a burst mode flag at its third input.

13. The system of claim 12, wherein the burst mode logic circuit includes an AND logic gate having a first input, a second input, and an output, the first input of the AND logic gate coupled to the output of the OR logic gate, and the second input of the AND logic gate coupled to the output of the PWM control circuit.

14. The system of claim 6, wherein the PWM control circuit includes an input, the input of the burst mode logic circuit is a first input of the burst mode logic circuit, and the burst mode logic circuit includes a second input;
the system further comprising:
a memory circuit storing instructions that, when executed, are configured to perform an interrupt service routine for determining a load state of the switch; and
a processor coupled to executively communicate with the memory circuit, the processor including an input, a first output, and a second output, the processor configured to receive a feedback signal at its first input, the first output of the processor coupled to the input of the PWM control circuit, and the second output of the processor coupled to the second input of the burst mode logic circuit.

15. A method of operating a pulse width modulation-controlled (PWM-controlled) system, comprising:
controlling a switch using a PWM control signal generated by a PWM control circuit operating in a burst mode corresponding to an underloaded condition of the PWM-controlled system, so that burst periods of the PWM control signal alternate with sleep periods of the PWM control signal;
determining that the PWM-controlled system has transitioned to a normal load condition in response to a feedback signal exceeding a nominal load threshold;
suppressing the sleep periods of the PWM control signal, while the PWM control circuit continues to operate in the burst mode, in response to the determining that the PWM-controlled system has transitioned to the normal load condition.

16. The method of claim 15, further comprising transitioning from burst mode to normal mode after the suppressing begins.

17. The method of claim 15, wherein the feedback signal is responsive to an output current of the PWM-controlled system.

18. The method of claim 15, wherein the feedback signal is a first feedback signal;
further comprising transitioning the PWM control circuit to operating in a normal mode corresponding to the normal load condition of the PWM-controlled system;
wherein the transitioning the PWM control circuit is performed in response to an interrupt service routine determining that a second feedback signal indicates the normal load condition; and
wherein the determining that the second feedback signal indicates the normal load condition is completed after the determining that the PWM-controlled system has transitioned to the normal load condition is completed.

19. The method of claim 18, wherein the first feedback signal is responsive to an output current of the PWM-controlled system, and the second feedback signal is responsive to an output voltage of the PWM-controlled system.

20. The method of claim 15, wherein the controlling is performed in response to a burst mode flag, an output of a comparator that performs the determining, a burst mask, and the PWM control signal.
